(19) United States
(12) Patent Application Publication
(10) Pub. No.: US 2012/0274193 A1
(43) Pub. Date: Nov. 1, 2012

(54) ENCLOSURE ASSEMBLY

(75) Inventor: GANG-QIANG QIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/433,495

(22) Filed: Mar. 29, 2012

(30) Foreign Application Priority Data
Apr. 27, 2011 (CN) 201110106460.9

(51) Int. Cl. H05K 7/20; H05K 5/02

(52) U.S. Cl. 312/236

(57) ABSTRACT

An enclosure assembly includes an enclosure, a rack and a blocking member. The enclosure includes a top plate. The rack is placed in the enclosure and defines an air inlet and an air outlet; and a gap is defined between the rack and the top plate. The blocking member includes a first locking piece, a second locking piece, and a connecting piece. The first locking piece is secured to the rack. The second locking piece is secured to the top plate. The connecting piece is connected and located between the first locking piece and the second locking piece. The blocking member covers the gap to prevent air from flowing from the air outlet to the air inlet.

### BACKGROUND

1. Technical Field

The present disclosure relates to enclosure assemblies, and particularly to an enclosure assembly of a container and a server.

2. Description of Related Art

In a data center container, a plurality of server racks is provided for securing a plurality of servers. A lot of heat is generated from the plurality of servers and dissipated to be distributed in the container. So, air flows from an air inlet of the server rack and flows out of the server rack via an air outlet of the server rack to cool the container. However, a gap is generally defined between the server rack and a top plate of the container for air to flow through. Thus, air flowing out of the air outlet may flow back via the gap and cause a lower cooling efficiency.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an enclosure assembly.

FIG. 2 is an isometric view of an assembly of a rack, a cushion, and a blocking member of the enclosure assembly of FIG. 1.

FIG. 3 is an assembled view of the enclosure assembly of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

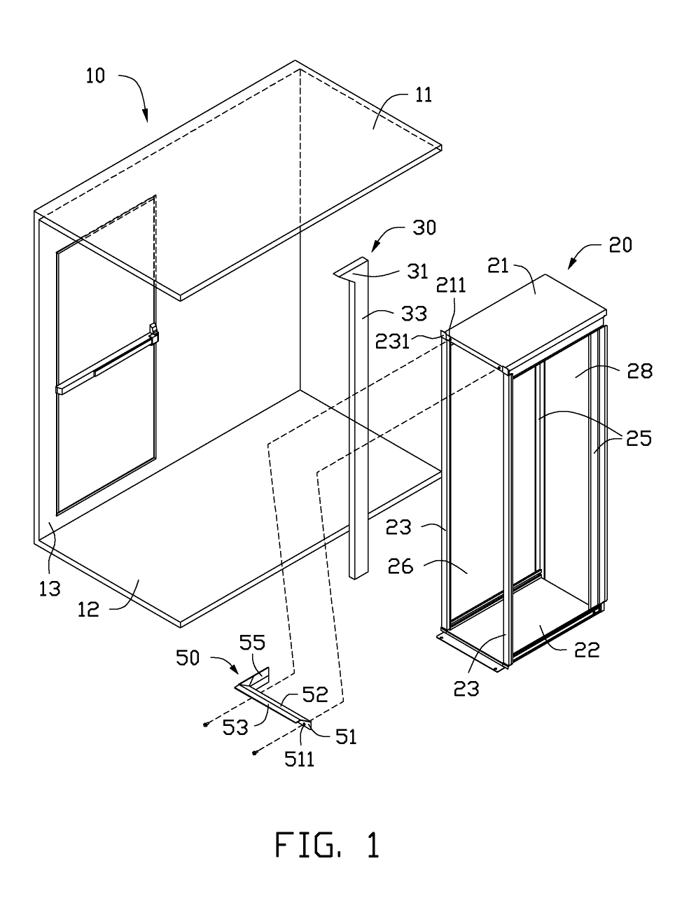

FIG. 1, is an enclosure assembly in accordance with an embodiment including an enclosure 10 (only a part shown in FIG. 1), a rack 20, a cushion 30, and a blocking member 50. In an embodiment, the enclosure 10 is a chassis of a data center container.

The enclosure 10 includes a top plate 11, a bottom plate 12, and a side plate 13. In one embodiment, the side plate 13 is substantially perpendicular to the top plate 11 and the bottom plate 12.

The rack 20, is adapted to secure a plurality of servers, including a top frame 21, a bottom frame 22, two first supports 23, and two second supports 25. The two first supports 23 and the two second supports 25 are located on four corners of the top frame 21 and the bottom frame 22. An air inlet 26 is defined by the top frame 21, the bottom frame 22 and the two first supports 23. An air outlet 28 is defined by the top frame 21, the bottom frame 22 and the two second supports 25. A mounting piece 231 extends from each of the two first supports 23. The mounting piece 231 is substantially parallel to a side surface of the top frame 21. A gap (not shown) is defined between the mounting piece 231 and the side surface of the top frame 21. The side surface of the top frame 21 defines two mounting holes 211 adjacent to the mounting piece 231.

The cushion 30 includes a first installation portion 31 and a second installation portion 33. The first installation portion 31 extends from a side of the second installation portion 33. In one embodiment, the first installation portion 31 is rectangular, and the second installation portion 33 is triangular. A height of the second installation portion 33 is substantially equal to a distance between the top plate 11 and the bottom plate 12. In one embodiment, the cushion 30 is made of foam.

The blocking member 50 includes a first locking piece 51, a second locking piece 53 and a connecting piece 52. The connecting piece 52 is connected and located between the first locking piece 51 and the second locking piece 53. The first locking piece 51 is substantially perpendicular to the second locking piece 53 and defines two first locking holes 511. A first angle is defined between the connecting piece 52 and the first locking piece 51. A second angle is defined between the connecting piece 52 and the second locking piece 53. The first angle and the second angle are obtuse. An installation piece 55 is connected to the first locking piece 51 and the connecting piece 52. In one embodiment, the installation piece 55 is substantially perpendicular to the first locking piece 51.

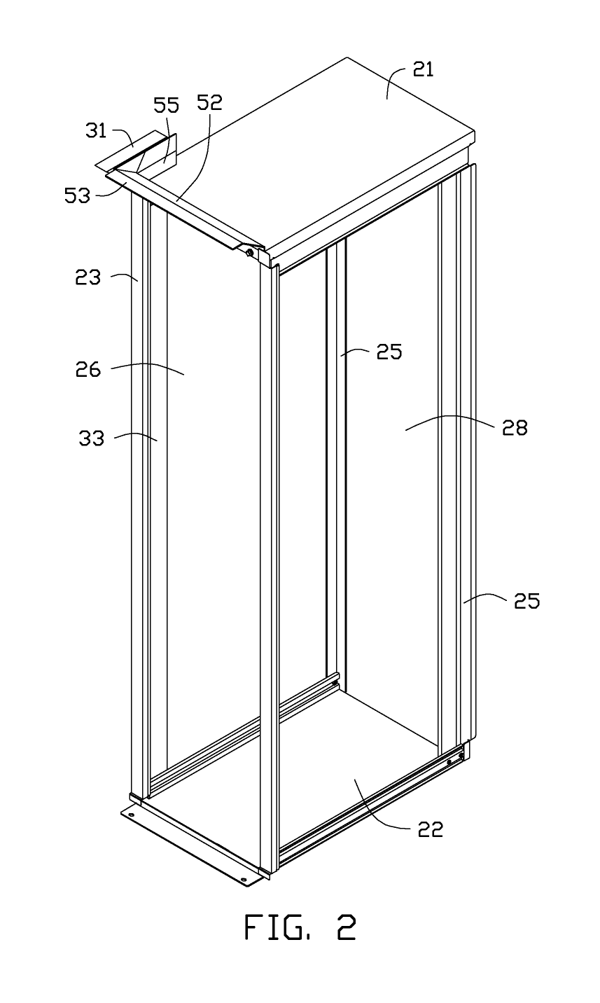

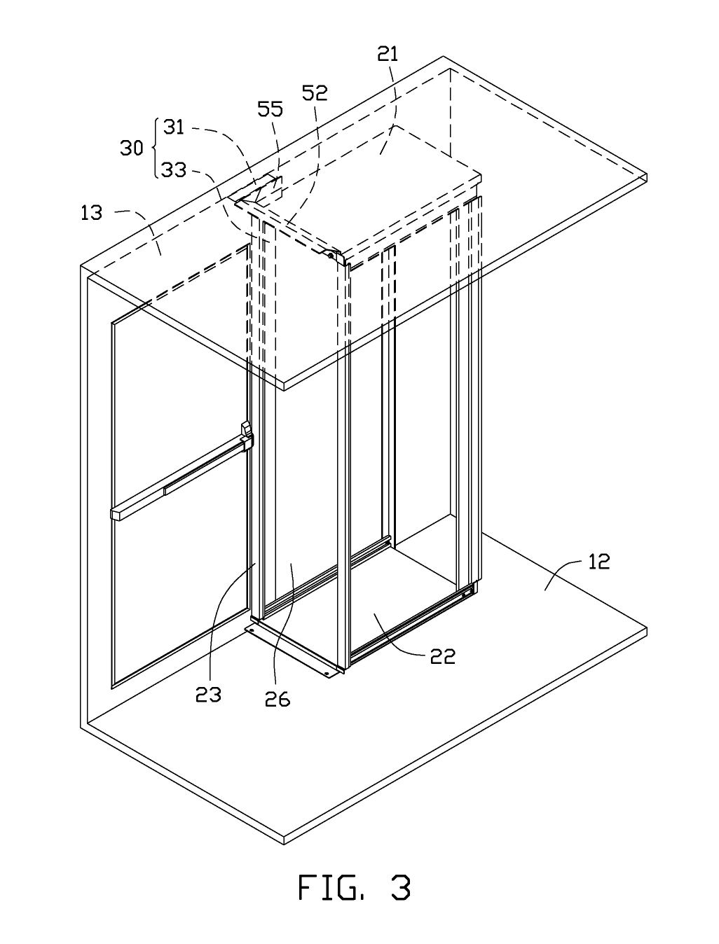

FIG. 2 and FIG. 3, show in assembly, the blocking member 50 is moved towards the rack 20. The first locking piece 51 is inserted between the mounting piece 231 and the top frame 21, and the first locking hole 511 is aligned to the mounting hole 211. A first locking member (not labeled), such as a screw, is inserted into the first locking hole 511 and the mounting hole 211, and the blocking member 50 is secured to the rack 20. The installation piece 55 abuts the top frame 21. The installation piece 55 is substantially parallel to an outer surface of the first support 23. A first side of the cushion 30 is secured to the rack 20. The first installation portion 31 is secured to the installation piece 55. The second installation portion 33 is secured to the outer surface of the first support 23.

The rack 20 is placed in the enclosure 10, the cushion 30 abuts the side plate 13, and the second locking piece 53 abuts the top plate 11. The bottom frame 22 is secured to the bottom plate 12. A second side of the cushion 30, opposite to the first side, is secured to the side plate 13. Thus, the cushion 30 seals a first aperture between the side plate 13 and the first support 23. The second locking piece 53 is elastically deformed and abuts the top plate 11. The second locking piece 53 and the connecting piece 52 seal a second aperture located between the top frame 21 and the top plate 11. The rack 20 is locked between the top plate 11 and the bottom plate 12, to prevent the rack 20 from moving when the rack 20 is shipped.

In use, air flows into the rack 20 through the air inlet 26 and than flows out of the rack 20 via the air outlet 28, to cool an electronic device secured in the rack 20. The first aperture between the side plate 13 and the first support 23 is sealed by the cushion 30. The second aperture between the top frame 21 and the top plate 11 is sealed by the second locking piece 53 and the connecting piece 52. Thus, air flowing out of the air outlet 28 is prevented from flowing back to the air inlet 26 through the first aperture and the second aperture.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An enclosure assembly comprising:
an enclosure comprising a top plate;
a rack placed in the enclosure and defining an air inlet and an air outlet; and a gap is defined between the rack and the top plate; and
a blocking member comprising a first locking piece, a second locking piece, and a connecting piece;
wherein the first locking piece is secured to the rack, the second locking piece is secured to the top plate, and the connecting piece is connected and located between the first locking piece and the second locking piece; and the blocking member covers the gap to prevent air flows from the air outlet to the air inlet.

2. The enclosure assembly of claim 1, wherein the first locking piece is substantially perpendicular to the second locking piece.

3. The enclosure assembly of claim 1, wherein a first angle is defined between the connecting piece and the first locking piece, and the first angle is obtuse.

4. The enclosure assembly of claim 1, wherein a second angle is defined between the connecting piece and the second locking piece, and the second angle is obtuse.

5. The enclosure assembly of claim 1, further comprising a side plate and a cushion, the side plate is substantially perpendicular to the top plate, and the cushion is secured between the side plate and the rack.

6. The enclosure assembly of claim 5, wherein the rack comprises a top frame, a bottom frame, two opposite first supports, and two opposite second supports; the air inlet is defined by the top frame, the bottom frame and the two opposite first supports; the air outlet is defined by the top frame, the bottom frame and the two opposite second supports; and air flows from the air inlet to the air outlet.

7. The enclosure assembly of claim 6, wherein the cushion is secured to one of the two opposite first supports.

8. The enclosure assembly of claim 6, wherein a mounting piece extends from each of the two opposite first supports, and the first locking piece is secured between the mounting piece and the top frame.

9. The enclosure assembly of claim 6, wherein the blocking member further comprises an installation piece connected to the first locking piece and the connecting piece, and the installation piece abuts the top frame and is substantially perpendicular to the top frame.

10. The enclosure assembly of claim 8, wherein the installation piece abuts the cushion, and the rack accommodates a plurality of server systems.

11. An enclosure assembly comprising:
an enclosure comprising a top plate, and a side plate substantially perpendicularly connected to the top plate;
a rack placed in the enclosure and defining an air inlet and an air outlet, a first aperture is defined between the rack and the top plate, and a second aperture is defined between the rack and the side plate;
a cushion secured between the rack and the side plate; and
a blocking member comprising a first locking piece, a second locking piece, and a connecting piece;
wherein the first locking piece is secured to the rack, the second locking piece is secured to the top plate, and the connecting piece is connected and located between the first locking piece and the second locking piece; the blocking member covers the first aperture and the cushion covers the second aperture, to prevent air flows from the air outlet to the air inlet.

12. The enclosure assembly of claim 11, wherein the first locking piece is substantially perpendicular to the second locking piece.

13. The enclosure assembly of claim 11, wherein a first angle is defined between the connecting piece and the first locking piece, and the first angle is obtuse.

14. The enclosure assembly of claim 11, wherein a second angle is defined between the connecting piece and the second locking piece, and the second angle is obtuse.

15. The enclosure assembly of claim 11, wherein the rack comprises a top frame, a bottom frame, two opposite first supports, and two opposite second supports; the air inlet is defined by the top frame, the bottom frame and the two opposite first supports; the air outlet is defined by the top frame, the bottom frame and the two opposite second supports; and air flows from the air inlet to the air outlet.

16. The enclosure assembly of claim 15, wherein the cushion is secured to one of the two opposite first supports.

17. The enclosure assembly of claim 15, wherein a mounting piece extends from each of the two opposite first supports, and the first locking piece is secured between the mounting piece and the top frame.

18. The enclosure assembly of claim 15, wherein the blocking member further comprises an installation piece connected to the first locking piece and the connecting piece, and the installation piece abuts the top frame and is substantially perpendicular to the top frame.

19. The enclosure assembly of claim 18, wherein the installation piece abuts the cushion, and the rack accommodates a plurality of server systems.

20. The enclosure assembly of claim 18, wherein the cushion comprises a first installation portion and a second installation portion, and the first installation portion extends from the second installation portion; the first installation portion is secured between the installation piece and the side plate, and the second installation portion is secured between the one of the two opposite first supports and the side plate.
